(19) United States
(12) Patent Application Publication
(10) Pub. No.: US 2025/0280618 A1
(43) Pub. Date: Sep. 4, 2025

(54) IMAGE SENSOR AND METHOD OF FABRICATING THE SAME

(71) Applicant: Taiwan Semiconductor Manufacturing Company, Ltd., Hsinchu (TW)

(72) Inventors: Chia-Chi Hsiao, Changhua County (TW); Chi-Hsien Chung, New Taipei City (TW); Tzu-Jui Wang, Kaohsiung City (TW); Chen-Jong Wang, Hsin-Chu (TW); Dun-Nian Yaung, Taipei City (TW)

(73) Assignee: Taiwan Semiconductor Manufacturing Company, Ltd., Hsinchu (TW)

(21) Appl. No.: 18/593,954

(22) Filed: Mar. 3, 2024

(51) Int. Cl. H01L 27/146

(52) U.S. Cl. CPC H10F 39/807; H10F 39/011; H10F 39/182; H10F 39/8063

(57) ABSTRACT

An image sensor includes first photosensing regions, second photosensing regions, a first deep well region, a first isolation structure and second isolation structures. The first and second photosensing regions are disposed within a substrate, and have a first conductivity type. The substrate includes a first surface and a second surface opposite to the first surface. The first deep well region has a second conductivity type, and is extending from the first surface to the second surface and physically separating the first photosensing regions from one another, and physically separating the second photosensing regions from one another. The first isolation structure is extending from the first surface to the second surface and laterally surrounding the first and second photosensing regions. The second isolation structures are extending from the first surface to the second surface, and disposed in between the first and second photosensing regions.

### BACKGROUND

Complementary Metal-Oxide-Semiconductor (CMOS) image sensors (CIS) are used in numerous applications including digital cameras, for example. Image sensors convert optical images to digital data that may be represented as digital images. An image sensor includes a pixel array (or grid) for detecting light and recording intensity (brightness) of the detected light. The pixel array responds to the light by accumulating a charge. The accumulated charge is then used (for example, by other circuitry) to provide a color and brightness signal for use in a suitable application, such as a digital camera.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1E are schematic top and sectional views of an image sensor in accordance with some embodiments of the present disclosure.

FIG. 2A to FIG. 4C are schematic sectional views of various stages in a method of fabricating an image sensor according to some exemplary embodiments of the present disclosure.

FIG. 5A and FIG. 5B are schematic sectional views of an image sensor in accordance with some other embodiments of the present disclosure.

FIG. 6A to FIG. 6E are schematic top and sectional views of an image sensor in accordance with some other embodiments of the present disclosure.

FIG. 7A to FIG. 9C are schematic sectional views of various stages in a method of fabricating an image sensor according to some other exemplary embodiments of the present disclosure.

FIG. 10A and FIG. 10B are schematic sectional views of an image sensor in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary metal-oxide semiconductor image sensors (CIS) having pixel sensors may comprise an array of photodetectors (e.g., a 2×2, 2×4, or 4×4 photodetector pixel sensor). In general, full isolation is required between adjacent photodetectors (or pixels) to reduce blooming and increase quantum efficiency (QE) in the CIS, while electron interflow is required between sub-pixels within the same photodetector (or same pixel). A deep trench isolation (DTI) structure may be disposed in/on a back-side surface of the substrate not only for pixel-to-pixel isolation, but also for inner-pixel isolation. As such, DTI structures generally have many etching depths, which in turn results in low DTI etching quality. For example, undesired etching profiles such as fences and shoulders may occur during the formation of these DTI structures with different depths (or heights).

In accordance with some embodiments of the present disclosure, an image sensor is fabricated so that the DTI architecture is simplified to improve the DTI etching quality. As such, the DTI structure in the image sensor can be formed with lower etching bias (lower damage), and a white pixel (WP) performance can be improved. In addition, by removing the DTI structure in between sub-pixels, an electron interflow region between the sub-pixels is no longer restricted by the DTI design, and can be arranged at any depth along the substrate.

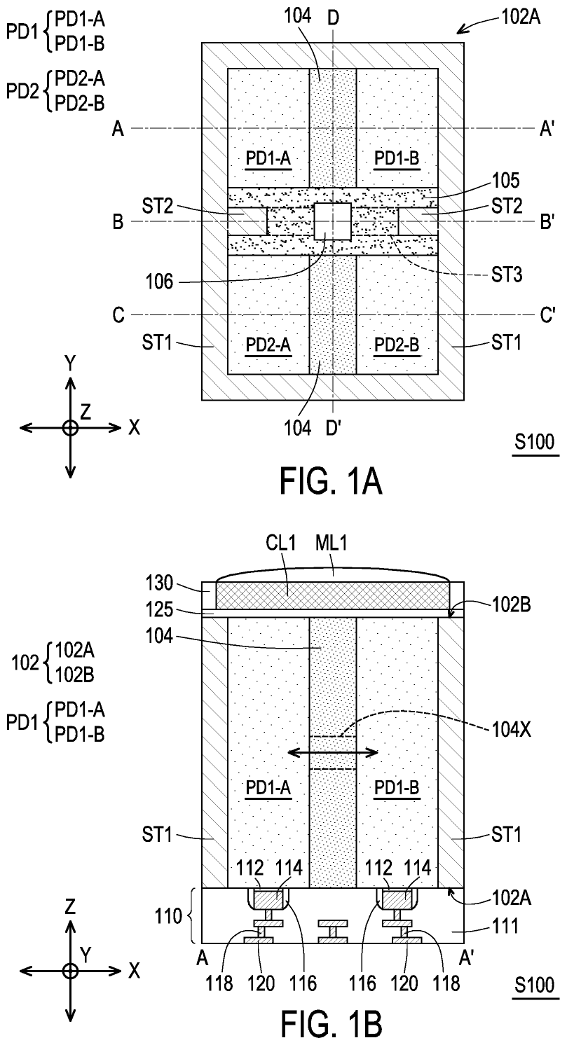

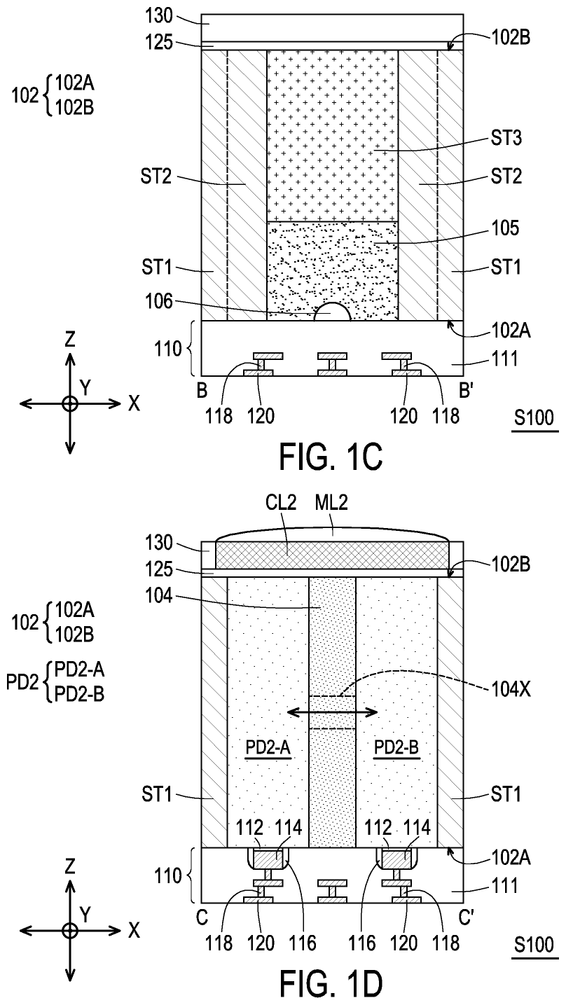

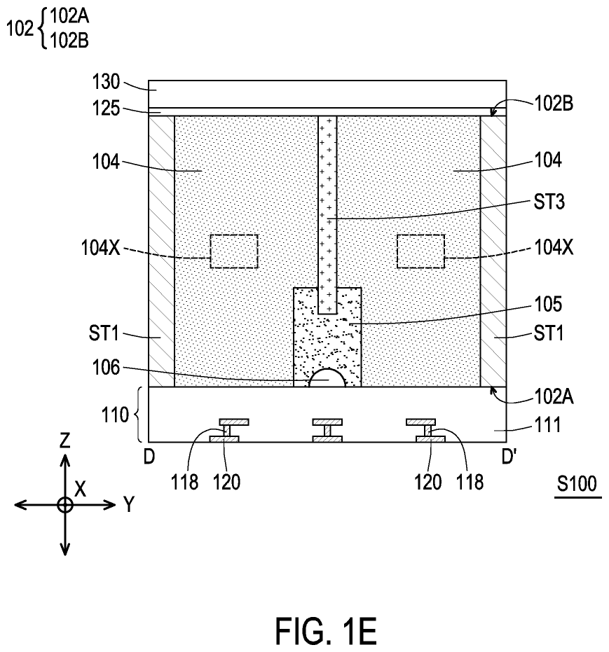

FIG. 1A to FIG. 1E are schematic top and sectional views of an image sensor S100 in accordance with some embodiments of the present disclosure. FIG. 1A is a top view of the image sensor S100 taken from a first surface 102A of the substrate 102. FIG. 1B is a sectional view of the image sensor S100 taken along the line A-A′ shown in FIG. 1A. FIG. 1C is a sectional view of the image sensor S100 taken along the line B-B′ shown in FIG. 1A. FIG. 1D is a sectional view of the image sensor S100 taken along the line C-C′ shown in FIG. 1A. FIG. 1E is a sectional view of the image sensor S100 taken along the line D-D′ shown in FIG. 1A.

As illustrated in FIG. 1A to FIG. 1E, the image sensor S100 of the present disclosure includes a substrate 102. In some embodiments, the substrate 102 may comprise any type of semiconductor body (e.g., silicon/CMOS bulk, SiGe, SOI, etc.) such as a semiconductor wafer or one or more die on a wafer, as well as any other type of semiconductor and/or epitaxial layers formed thereon and/or otherwise associated therewith.

Referring to FIG. 1A, FIG. 1B and FIG. 1D, a first photodetector PD1 and a second photodetector PD2 are disposed within the substrate 102. For example, the first photodetector PD1 includes a first sub-pixel region PD1-A and a second sub-pixel region PD1-B, while the second photodetector PD2 includes a third sub-pixel region PD2-A and a fourth sub-pixel region PD2-B. In the exemplary embodiment, the first photodetector PD1 and the second photodetector PD2 are formed by doping the substrate 102 with a first dopant having a first conductivity type (e.g. n-type). In certain embodiments, a doping concentration of the first photodetector PD1 and a second photodetector PD2 are within a range of about 10¹⁴ to 10¹⁸ atoms/cm³, or another suitable value. In some embodiments, the first sub-pixel region PD1-A and the second sub-pixel region PD1-B are first photosensing regions (PD1-A, PD1-B) of the first photodetector PD1, while the third sub-pixel region PD2-A and the fourth sub-pixel region PD2-B are second photosensing regions (PD2-A, PD2-B) of the second photodetector PD2, whereby the photosensing regions are configured to convert radiation into an electric signal.

As shown in FIG. 1A to FIG. 1E, the first sub-pixel region PD1-A, the second sub-pixel region PD1-B, the third sub-pixel region PD2-A, and the fourth sub-pixel region PD2-B extends from the first surface 102A of the substrate 102 to the second surface 102B of the substrate 102. In the exemplary embodiment, a first deep well region 104 is disposed in between the first sub-pixel region PD1-A and the second sub-pixel region PD1-B, and disposed in between the third sub-pixel region PD2-A and the fourth sub-pixel region PD2-B. In other words, the first deep well region 104 is extending along the Y-direction and the Z-direction, and physically separating the first photosensing regions (PD1-A, PD1-B) from one another, and physically separating the second photosensing regions (PD2-A, PD2-B) from one another. In certain embodiments, the first deep well region 104 is formed by doping the substrate 102 with a second dopant having a second conductivity type (e.g. p-type), wherein the second conductivity type is opposite to the first conductivity type of the first photodetector PD1 and the second photodetector PD2. In one embodiment, the first sub-pixel region PD1-A, the second sub-pixel region PD1-B, the third sub-pixel region PD2-A and the fourth sub-pixel region PD2-B are n-type doped regions, while the first deep well region 104 is a p-type doped region.

As illustrated in FIG. 1B, FIG. 1D and FIG. 1E, in some embodiments, the first deep well region 104 includes an electron interflow region 104X (first electron interflow region) allowing electrons to pass from the first sub-pixel region PD1-A to the second sub-pixel region PD1-B along the X-direction, and another electron interflow region 104X (second electron interflow region) allowing electrons to pass from the third sub-pixel region PD2-A to the fourth sub-pixel region PD2-B along the X-direction. As shown in FIG. 1B and FIG. 1D, the electron interflow regions 104X are located near a center position in the first deep well region 104 for providing electron interflow between the sub-pixel regions (PD1-A and PD1-B, or PD2-A and PD2-B). However, the disclosure is not limited thereto, and a position of the electron interflow regions 104X in the first deep well region 104 may be adjusted based on design requirements. In the exemplary embodiment, the electron interflow regions 104X are regions having a lowest doping concentration in the first deep well region 104. In other words, when the first deep well region 104 is doped with a P-type dopant, the electron interflow regions 104X have the lowest doping concentration of the P-type dopant in the first deep well region 104. In some embodiments, the first deep well region 104 may include various doped regions with a doping concentration in a range of 10¹² atoms/cm³ to about 10¹⁴ atoms/cm³. In certain embodiments, the electron interflow regions 104X have a doping concentration that is lower than 10¹² atoms/cm³.

As further illustrated in FIG. 1A to FIG. 1E, the image sensor S100 further includes a first isolation structure ST1 that is extending from the first surface 102A to the second surface 102B of the substrate 102. In some embodiments, the first isolation structure ST1 is laterally surrounding the first photodetector PD1 and the second photodetector PD2, or laterally surrounding the first photosensing regions (PD1-A, PD1-B) and the second photosensing regions (PD2-A, PD2-B). For example, the first isolation structure ST1 is physically contacting side surfaces of the first sub-pixel region PD1-A, the second sub-pixel region PD1-B, the third sub-pixel region PD2-A, and the fourth sub-pixel region PD2-B. Furthermore, a top surface and a bottom surface of the first isolation structure ST1 are leveled with top surfaces and bottom surfaces of the first photodetector PD1 and the second photodetector PD2.

In some embodiments, the first isolation structure ST1 is formed of an isolation material and a liner layer surrounding the isolation material (not shown). For example, the liner layer separates the isolation material from the substrate 102. In some embodiments, the isolation material may, for example, be or comprise an oxide, such as silicon dioxide, while the liner layer may, for example, be or comprise a high-k dielectric material. In some embodiments, the liner layer may be or comprise hafnium oxide, titanium oxide, aluminum oxide, zirconium oxide, another suitable dielectric material, or the like. In certain embodiments, the first isolation structure ST1 is referred as a deep trench isolation (DTI) structure.

In some embodiments, the second photodetector PD2 is physically separated from the first photodetector PD1 by a second deep well region 105, by second isolation structures ST2 and by a third isolation structure ST3 (or auxiliary isolation structure). In the exemplary embodiment, the second isolation structures ST2 are extending from the first surface 102A to the second surface 102B of the substrate 102, and is disposed in between the first photosensing regions (PD1-A, PD1-B) and the second photosensing regions (PD2-A, PD2-B) separating the first photodetector PD1 from the second photodetector PD2. In certain embodiments, the second isolation structures ST2 are physically joined with the first isolation structure ST1, and are contacting sidewalls of the third isolation structure ST3 (auxiliary isolation structure), and contacting sidewalls of the second deep well region 105 (see FIG. 1C). Furthermore, a height of the second isolation structures ST2 is equal to the height of the first isolation structure ST1. In some embodiments, the second isolation structures ST2 is formed of a material similar to the first isolation structure ST1. In other words, the second isolation structures ST2 may be formed of an isolation material and a liner layer surrounding the isolation material (not shown), whereby the isolation material comprises an oxide, while the liner layer comprises a high-k dielectric material.

As illustrated in FIG. 1A, FIG. 1C and FIG. 1E, the second deep well region 105 is extending from the first surface 102A of the substrate 102 to a first depth into the substrate 102. The first depth is not particularly limited as long as the second deep well region 105 is partially overlapped with the third isolation structure ST3 (auxiliary isolation structure) along the Y-direction (see FIG. 1E). In some embodiments, the second deep well region 105 is physically separating the first photosensing regions (PD1-A, PD1-B) from the second photosensing regions (PD2-A, PD2-B). In certain embodiments, the second deep well region 105 is physically separating the first sub-pixel region PD1-A and the second sub-pixel region PD1-B from the third sub-pixel region PD2-A and the fourth sub-pixel region PD2-B. Furthermore, the second deep well region 105 is formed by doping the substrate 102 with a second dopant having a second conductivity type (e.g. p-type), whereby the second deep well region 105 has a higher doping concentration than the first deep well region 105. For example, when the first deep well region 104 has a doping concentration in a range of 10¹² atoms/cm³ to about 10¹⁴ atoms/cm³, the second deep well region 105 has s a doping concentration in a range of 10¹⁴ atoms/cm³ to about 10¹⁸ atoms/cm³.

In some embodiments, the third isolation structure ST3 (auxiliary isolation structure) is extending from the second surface 102B of the substrate 102 along a Z-direction towards a position into the second deep well region 105. In other words, the third isolation structure ST3 (auxiliary isolation structure) protrudes into, or is partially covered by the second deep well region 105. In the exemplary embodiment, the third isolation structure ST3 (auxiliary isolation structure) is physically separating the first sub-pixel region PD1-A and the second sub-pixel region PD1-B from the third sub-pixel region PD2-A and the fourth sub-pixel region PD2-B. Furthermore, the third isolation structure ST3 (auxiliary isolation structure) is joined to the second deep well region 105, and a height of the third isolation structure ST3 (auxiliary isolation structure) is smaller than a height of the first isolation structure ST1.

In some embodiments, the third isolation structure ST3 (auxiliary isolation structure) is formed of a material similar to the first isolation structure ST1 and the second isolation structure ST2. In other words, the third isolation structure ST3 (auxiliary isolation structure) may be formed of an isolation material and a liner layer surrounding the isolation material (not shown), whereby the isolation material comprises an oxide, while the liner layer comprises a high-k dielectric material. In various embodiments, the first isolation structure ST1 and the second isolation structure ST2 may be referred to as a full-depth DTI structure, while the e third isolation structure ST3 (auxiliary isolation structure) may be referred to as a partial-depth DTI structure.

As further illustrated in FIG. 1A, FIG. 1C and FIG. 1E, a floating diffusion node 106 is disposed in the substrate 102 and located in between the second isolation structures ST2. In some embodiments, the floating diffusion node 106 is embedded in the second deep well region 105 and overlapped with the third isolation structure ST3 (auxiliary isolation structure) along the Z-direction. The floating diffusion node 106 may comprises the first conductivity type (e.g. n-type). In various embodiments, the floating diffusion node 106 may be disposed at a center of adjacent photodetectors. For example, the floating diffusion node 106 is disposed at a center in between the first sub-pixel region PD1-A, the second sub-pixel region PD1-B, the third sub-pixel region PD2-A, and the fourth sub-pixel region PD2-B.

In some embodiments, the first photodetector PD1 and the second photodetector PD2 are configured to absorb incident light (e.g., photons) and generate respective electrical signals corresponding to the incident light. In such embodiments, the first photodetector PD1 and the second photodetector PD2 may generate electron-hole pairs from the incident light. In various embodiments, transistor devices (112, 114) located on the first surface 102A of the substrate may be configured to conduct readout of the generated electrical signals from the first photodetector PD1 and the second photodetector PD2. For example, the transistor devices comprise a gate electrode 114 and a gate dielectric layer 112 disposed between the gate electrode 114 and the first surface 102A of the substrate 102. The gate electrode 114 may, for example, be or comprise polysilicon, a metal material such as aluminum, titanium, tantalum, tungsten, another metal material, or any combination of the foregoing. The gate dielectric layer 112 may, for example, be or comprise silicon dioxide, a high-k dielectric material such as tantalum oxide, hafnium oxide, aluminum oxide, another dielectric material, or the like. In certain embodiments, spacer structures 116 are further formed aside the gate dielectric layer 112 and the gate electrode 114.

In some embodiments, the transistor devices (112, 114) are respectively located on each of the sub-pixel regions (PD1-A, PD1-B, PD2-A and PD2-B) of the first photodetector PD1 and the second photodetector PD2. In certain embodiments, the transistor devices (112, 114) are configured to selectively form a conductive channel in the substrate 102 between the floating diffusion node 106 and adjacent photodetectors (PD1, PD2) to transfer accumulated charge (e.g., via absorbing incident radiation) in the photodetectors (PD1, PD2) to the floating diffusion node 106.

As further illustrated in FIG. 1B to FIG. 1E, in some embodiments, an interconnect structure 110 is formed over the first surface 102A of the substrate 102. The interconnect structure 110 comprises an interconnect dielectric structure 111, a plurality of conductive wires 120, and a plurality of conductive vias 118. The transistor devices (112, 114) may be electrically coupled to the conductive vias 118 and/or the conductive wires 120. In some embodiments, the interconnect dielectric structure 111 comprise one or more dielectric layers that may each, for example, be or comprise silicon dioxide, a low-k dielectric material, an extreme low-k dielectric material, or any combination of the foregoing. In some embodiments, the low-k dielectric material is a dielectric material with a dielectric constant less than 3.9. Furthermore, the conductive vias 118 and the conductive wires 120 may, for example, each be or comprise aluminum, copper, ruthenium, tungsten, another conductive material, or any combination of the foregoing.

As shown in FIG. 1B and FIG. 1D, a dielectric layer 125 is disposed on the second surface 102B of the substrate 102. In some embodiments, the dielectric layer 125 comprise an oxide, such as silicon dioxide, or the like. In some embodiments, a grid structure 130 is disposed on the dielectric layer 125, whereby the grid structure 130 includes a plurality of openings overlying the sub-pixel regions (PD1-A, PD1-B, PD2-A and PD2-B) of the first photodetector PD1 and the second photodetector PD2. In the exemplary embodiment, a first color filter CL1 and a second color filter CL2 are disposed in the openings of the grid structure. For example, the first color filter CL1 is overlapped with the first photosensing regions (PD1-A, PD1-B) and the first deep well region 104 of the first photodetector PD1, while the second color filter CL2 is overlapped with the second photosensing regions (PD2-A, PD2-B) and the first deep well region 104 of the second photodetector PD2. The first color filter CL1 and the second color filter CL2 are configured to transmit specific wavelengths of incident light while blocking other wavelengths of incident light. In one embodiment, the first color filter CL1 may transmit light having wavelengths within a first range, while the second color filter CL2 may transmit light having wavelengths within a second range different than the first range.

Furthermore, in some embodiments, a first micro-lens ML1 and a second micro-lens ML2 are respectively disposed on the first color filter CL1 and the second color filter CL2, and are configured to focus the incident light towards the photodetectors (PD1, PD2). In some embodiments, the first micro-lens ML1 is disposed on and overlapped with the first photosensing regions (including the first sub-pixel region PD1-A, second sub-pixel region PD1-B), and the first deep well region 104. Furthermore, the second micro-lens ML2 is separated from the first micro-lens, and disposed on and overlapped with the second photosensing regions (including the third sub-pixel region PD2-A, fourth sub-pixel region PD2-B), and the first deep well region 104. During operation of the image sensor S100, the incident radiation or incident light is focused by the micro-lens (ML1 or ML2) to the underlying photosensing regions, where an electron-hole pair may be generated to produce a photocurrent. Up to here, an image sensor S100 according to some exemplary embodiments of the present disclosure may be accomplished.

In the exemplary embodiment, the image sensor S100 has a simplified DTI architecture including the first isolation structure ST1, the second isolation structures ST2 and the third isolation structure ST3 (or auxiliary isolation structure). As such, the DTI structure in the image sensor S100 can be formed with lower etching bias (lower damage), and a white pixel (WP) performance can be improved. In addition, by removing the DTI structure in between sub-pixels (between PD1-A and PD1-B, or between PD2-A and PD2-B), an electron interflow region between the sub-pixels is no longer restricted by the DTI design, and can be arranged at any depth along the substrate 102. As such, a more flexible design of the image sensor S100 can be achieved.

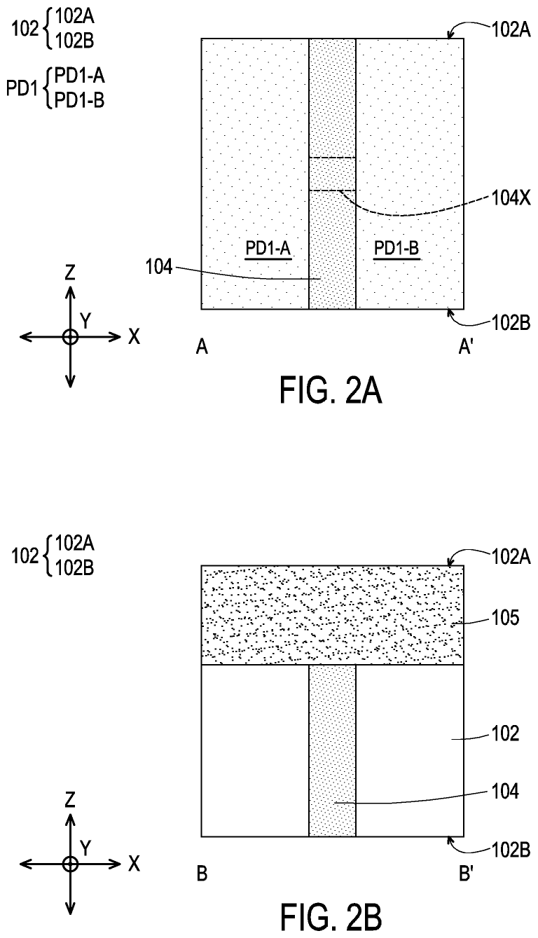

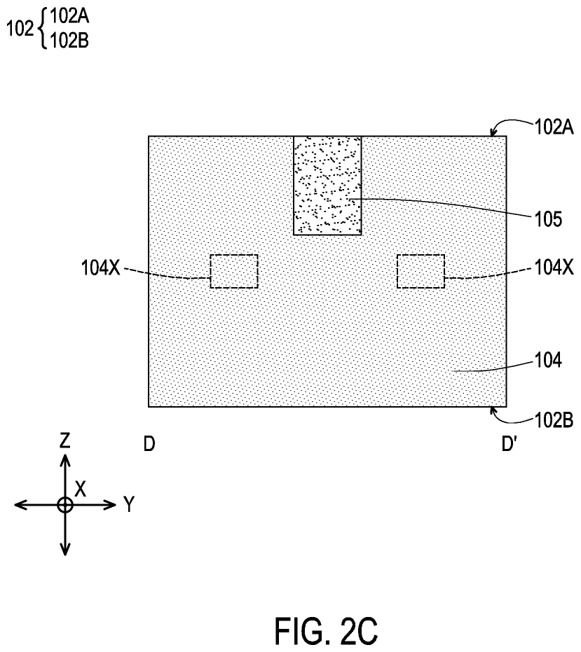

In the exemplary embodiment, the image sensor S100 shown in FIG. 1A to FIG. 1E is formed by a backside DTI etching process. The method of fabricating the image sensor S100 will be described in further detail by referring to FIG. 2A to FIG. 4C.

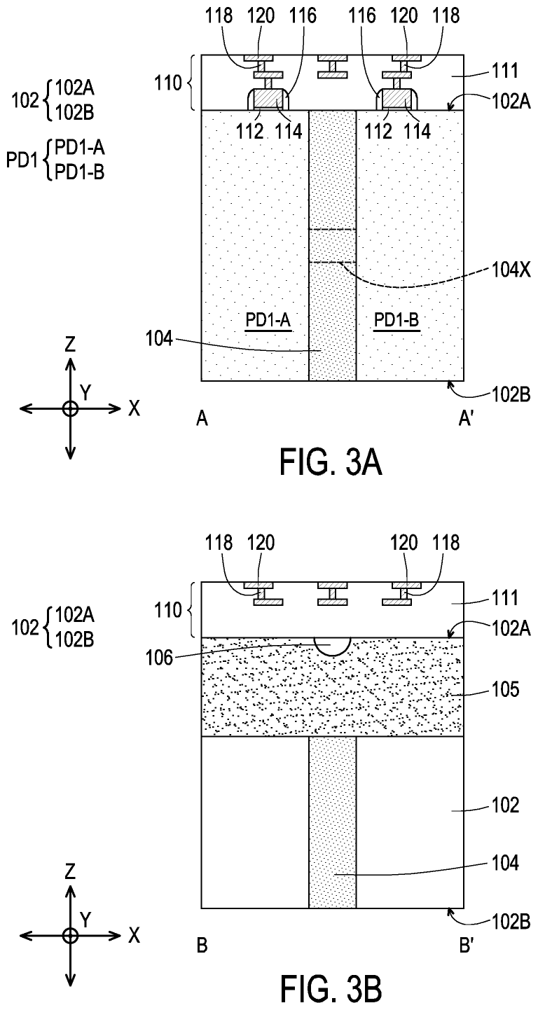

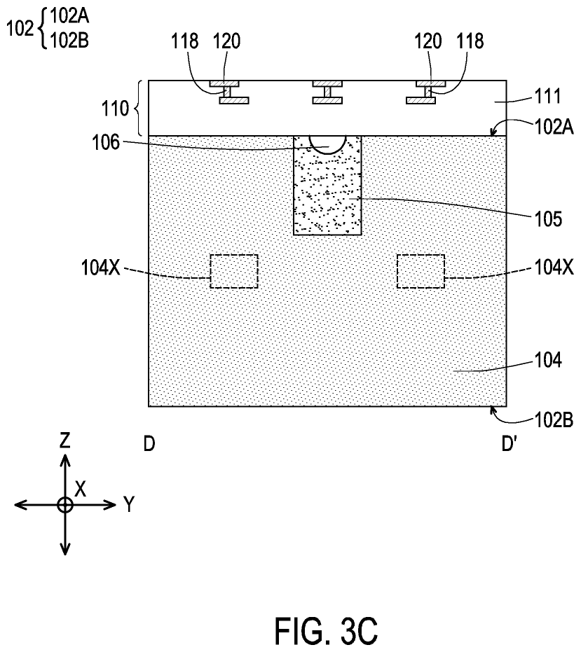

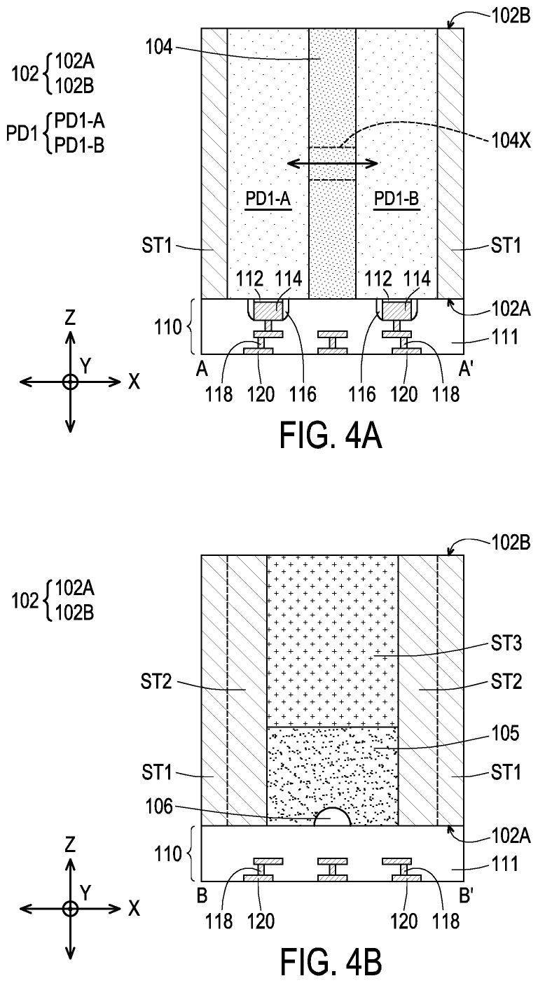

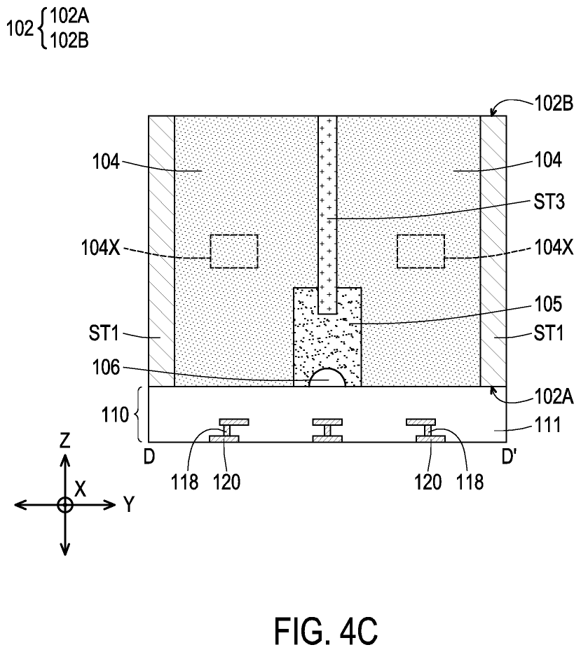

FIG. 2A to FIG. 4C are schematic sectional views of various stages in a method of fabricating the image sensor S100 according to some exemplary embodiments of the present disclosure. FIG. 2A, FIG. 3A and FIG. 4A illustrates sectional views of various stages of fabricating the image sensor S100 corresponding to a position taken along the line A-A′ shown in FIG. 1A. Similarly, FIG. 2B, FIG. 3B and FIG. 4B illustrates sectional views of various stages of fabricating the image sensor S100 corresponding to a position taken along the line B-B′ shown in FIG. 1A. Similarly, FIG. 2C, FIG. 3C and FIG. 4C illustrates sectional views of various stages of fabricating the image sensor S100 corresponding to a position taken along the line D-D′ shown in FIG. 1A. The reference numerals used in FIG. 2A to FIG. 4C are the same as those used in FIG. 1A to FIG. 1E, thus the details are the same as that described in FIG. 1A to FIG. 1E, and some description will be omitted herein.

Referring to FIG. 2A to FIG. 2C, in some embodiments, a substrate 102 is first provided. As shown in FIG. 2A, the substrate 102 is doped with a first dopant having a first conductivity type (e.g. n-type) to form the first photodetector PD1 including the first sub-pixel region PD1-A and the second sub-pixel region PD1-B (the first photosensing region). The second photodetector PD2 is formed in a similar manner, thus its details will be omitted herein. In some embodiments, the substrate 102 is further doped to form the first deep well region 104 and the second deep well region 105 of the second conductivity type (e.g. p-type). For example, the substrate 102 is doped so that the second deep well region 105 has a higher doping concentration than the first deep well region 104. Furthermore, in some embodiments, some regions in the first deep well region 104 are non-doped, lightly doped, or doped with a lower concentration to form electron interflow regions 104X, which allows electron interflow between the sub-pixels (between PD1-A and PD1-B, or between PD2-A and PD2-B).

In the exemplary embodiment, an ion implantation process is performed on the first surface 102A of the substrate 102 to form the doped regions in the first photodetector PD1 and the second photodetector PD2, and to form the first deep well region 104 and the second deep well region 105. For example, the ion implantation process comprises: selectively forming a masking layer (not shown) over the first surface 102A of the substrate 102; performing a selective ion implantation process according to the masking layer, thereby implanting one or more dopants within the substrate 102; and performing a removal process to remove the masking layer (not shown).

Referring to FIG. 3A to FIG. 3C, in a subsequent step, a further ion implantation process is performed on the first surface 102A of the substrate 102 to form the floating diffusion node 106 in the second deep well region 105. Subsequently, transistor devices (112, 114) and the interconnect structure 110 are formed over the first surface 102A of the substrate 102. In the exemplary embodiment, the gate dielectric layer 112 and the gate electrode 114 are formed on the substrate 102 by deposition processes such as, atomic layer deposition (ALD), chemical vapor deposition (CVD), physical vapor deposition (PVD), or the like. In yet another embodiment, the transistor devices (112, 114) may be formed by one or more deposition processes, one or more patterning processes, one or more planarization processes, one or more ion implantation processes, and/or some other suitable processes.

Furthermore, in the exemplary embodiment, forming the interconnect structure 110 includes forming conductive vias 118 and conductive wires 120, and forming interconnect dielectric structure 111 surrounding the transistor devices (112, 114) and surrounding the conductive vias 118 and conductive wires 120. In some embodiments, the interconnect dielectric structure 111 formed by one or more deposition process(es) such as a physical vapor deposition (PVD) process, a chemical vapor deposition (CVD) process, an atomic layer deposition (ALD) process, another suitable growth or deposition process, or any combination of the foregoing. Furthermore, the conductive vias 118 and conductive wires 120 may be formed by one or more deposition processes, one or more patterning processes, one or more planarization processes, or some other suitable processes.

Referring to FIG. 4A to FIG. 4C, after forming the interconnect structure 110 on the first surface 102A of the substrate 102, the structure illustrated in FIG. 3A to FIG. 3C is flipped around to reveal the second surface 102B of the substrate 102. In the exemplary embodiment, the substrate 102 is partially removed or patterned to form a plurality of trench openings, whereby an isolation material and a liner layer are formed in the trench openings to form the first isolation structure ST1, the second isolation structure ST2 and the third isolation structure ST3 (or auxiliary isolation structure). In some embodiments, the trench openings are formed by etching (e.g., by a dry etch process and/or a wet etch process) designated regions of the substrate 102 using a masking layer. After forming the trench openings, the isolation material and the liner layer of the isolation structures (ST1, ST2, ST3) may be respectively deposited in the trench openings by a CVD process, a PVD process, an ALD process, and/or some other suitable deposition or growth process.

After forming the isolation structures (ST1, ST2, ST3) shown in FIG. 4A to FIG. 4C, a dielectric layer 125, a grid structure 130, the color filters (CL1, CL2) and the micro-lens (ML1, ML2) may be respectively formed/disposed over the second surface 102B of the substrate 102 to accomplish the image sensor S100 illustrated in FIG. 1A to FIG. 1E.

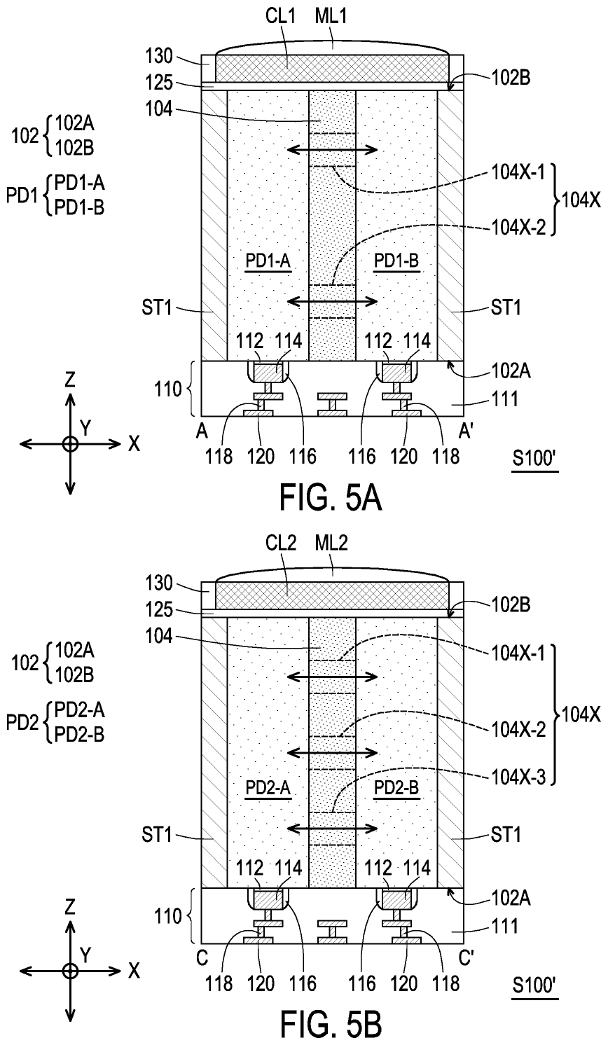

FIG. 5A and FIG. 5B are schematic sectional views of an image sensor in accordance with some other embodiments of the present disclosure. The image sensor S100′ illustrated in FIG. 5A and FIG. 5B is similar to the image sensor S100 illustrated in FIG. 1A to FIG. 1E. Therefore, the same reference numerals are used to refer to the same or like parts, and its detailed description will be omitted herein. The difference between the embodiments is in the design of the electron interflow region 104X.

In the embodiment illustrated in FIG. 1A to FIG. 1E the first deep well region 104 includes a single electron interflow region 104X (first electron interflow region) in the first photodetector PD1 allowing electrons to pass from the first sub-pixel region PD1-A to the second sub-pixel region PD1-B, and a single electron interflow region 104X (second electron interflow region) in the second photodetector allowing electrons to pass from the third sub-pixel region PD2-A to the fourth sub-pixel region PD2-B. However, the disclosure is not limited thereto, and there may be multiple electron interflow regions 104X (or sub-regions) in the first photodetector PD1 and the second photodetector PD2. For example, referring to FIG. 5A, in the first photodetector PD1, the electron interflow region 104X (first electron interflow region) includes a plurality of electron interflow sub-regions 104X-1, 104X-2 allowing electrons to pass from the first sub-pixel region PD1-A to the second sub-pixel region PD1-B. Furthermore, referring to FIG. 5B, in the second photodetector PD2, the electron interflow region 104X (second electron interflow region includes a plurality of electron interflow sub-regions 104X-1, 104X-2, 104X-3 allowing electrons to pass from the third sub-pixel region PD2-A to the fourth sub-pixel region PD2-B. For example, the number of electron interflow region 104X (or sub-regions) in the first photodetector PD1 and the second photodetector PD2 may be different.

In the exemplary embodiment, the image sensor S100′ has a simplified DTI architecture including the first isolation structure ST1, the second isolation structures ST2 and the third isolation structure ST3 (or auxiliary isolation structure). As such, the DTI structure in the image sensor S100 can be formed with lower etching bias (lower damage), and a white pixel (WP) performance can be improved. In addition, by removing the DTI structure in between sub-pixels (between PD1-A and PD1-B, or between PD2-A and PD2-B), an electron interflow region between the sub-pixels is no longer restricted by the DTI design, and multiple electron interflow regions may be formed between sub-pixels.

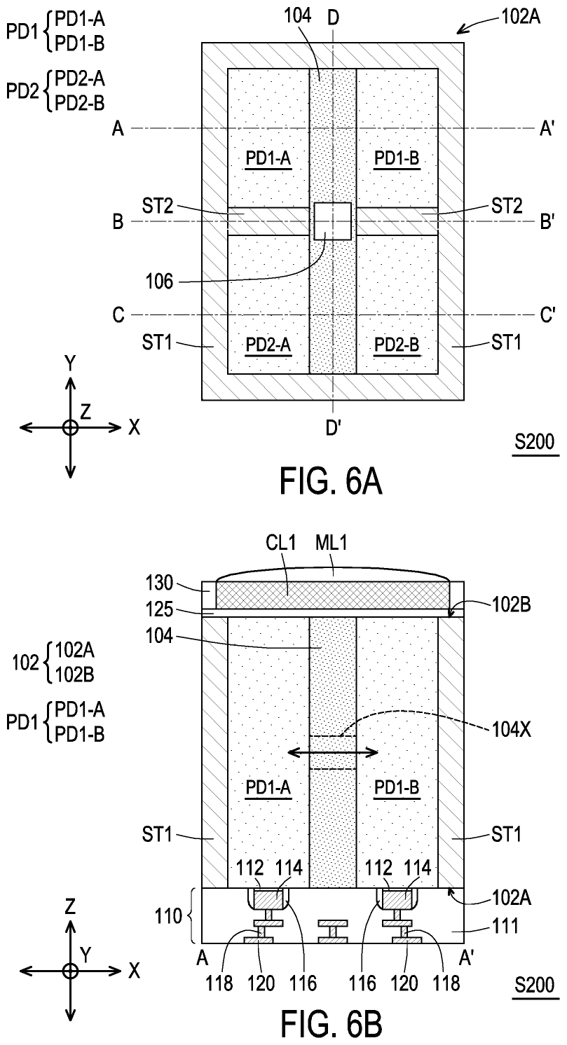

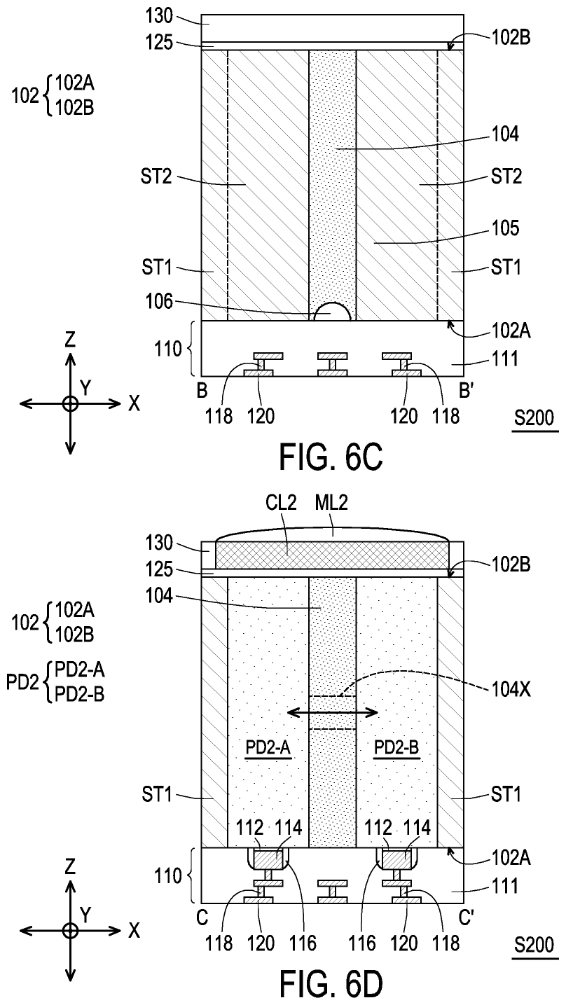

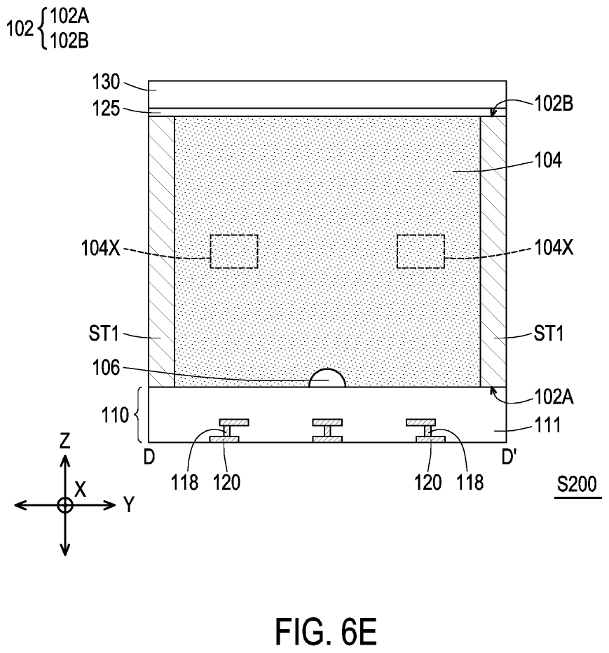

FIG. 6A to FIG. 6E are schematic top and sectional views of an image sensor in accordance with some other embodiments of the present disclosure. FIG. 6A is a top view of the image sensor S200 taken from a first surface 102A of the substrate 102. FIG. 6B is a sectional view of the image sensor S200 taken along the line A-A′ shown in FIG. 6A. FIG. 6C is a sectional view of the image sensor S200 taken along the line B-B′ shown in FIG. 6A. FIG. 6D is a sectional view of the image sensor S200 taken along the line C-C′ shown in FIG. 6A. FIG. 6E is a sectional view of the image sensor S200 taken along the line D-D′ shown in FIG. 6A. The image sensor S200 illustrated in FIG. 6A and FIG. 6E is similar to the image sensor S100 illustrated in FIG. 1A to FIG. 1E. Therefore, the same reference numerals are used to refer to the same or like parts, and its detailed description will be omitted herein. The difference between the embodiments is that the second deep well region 105 and the third isolation structure ST3 (or auxiliary isolation structure) are removed from the image sensor S200.

As illustrated in FIG. 6A to FIG. 6E, when the second deep well region 105 and the third isolation structure ST3 (or auxiliary isolation structure) are removed, the first deep well region 104 may be designed to extend along the Y-direction from the first photodetector PD1 to the second photodetector PD2. For example, the first deep well region 104 may physically separate the first sub-pixel region PD1-A from the second sub-pixel region PD1-B, and physically separate the third sub-pixel region PD2-A from the fourth sub-pixel region PD2-B. Furthermore, the first deep well region 104 may physically separate the adjacent second isolation structures ST2.

In the exemplary embodiment, the second isolation structures ST2 are extending from the first surface 102A to the second surface 102B of the substrate 102, and further extending along the X-direction to contact the sidewalls of the first deep well region 104. In various embodiments, the second isolation structures ST2 physically separates the first sub-pixel region PD1-A from the third sub-pixel region PD2-A, and physically separates the second sub-pixel region PD1-B from the fourth sub-pixel region PD2-B.

In the image sensor S200 of FIG. 6A to FIG. 6E, the image sensor S200 has a further simplified DTI architecture including the first isolation structure ST1 and the second isolation structures ST2. As such, the DTI structure in the image sensor S200 can be formed with lower etching bias (lower damage), and a white pixel (WP) performance can be improved. In addition, by removing the DTI structure in between sub-pixels (between PD1-A and PD1-B, or between PD2-A and PD2-B), an electron interflow region between the sub-pixels is no longer restricted by the DTI design, and can be arranged at any depth along the substrate 102. As such, a more flexible design of the image sensor S200 can be achieved.

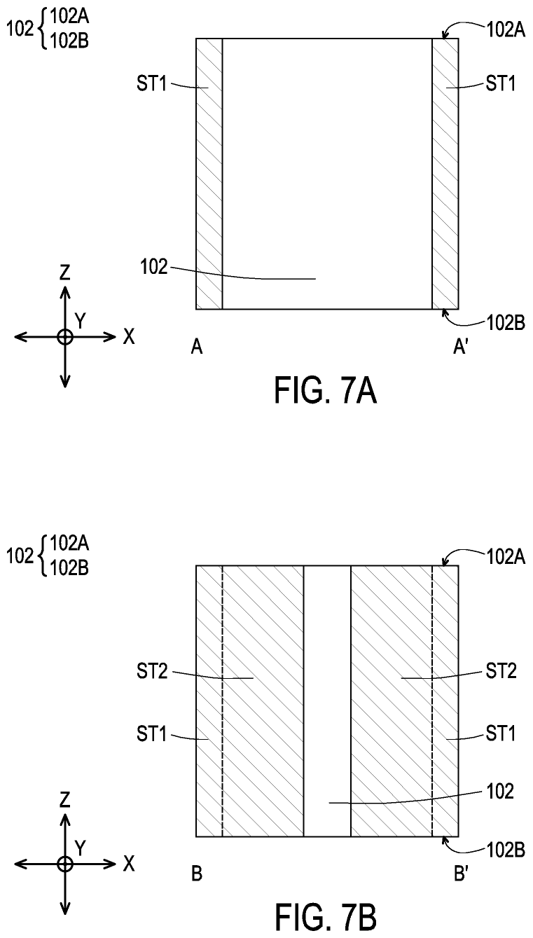

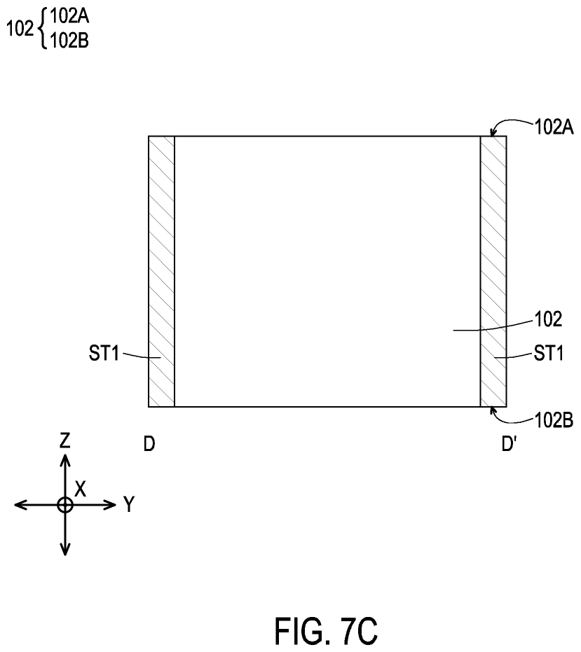

In the exemplary embodiment, the image sensor S200 shown in FIG. 6A to FIG. 6E is formed by a front side DTI etching process. The method of fabricating the image sensor S200 will be described in further detail by referring to FIG. 7A to FIG. 9C.

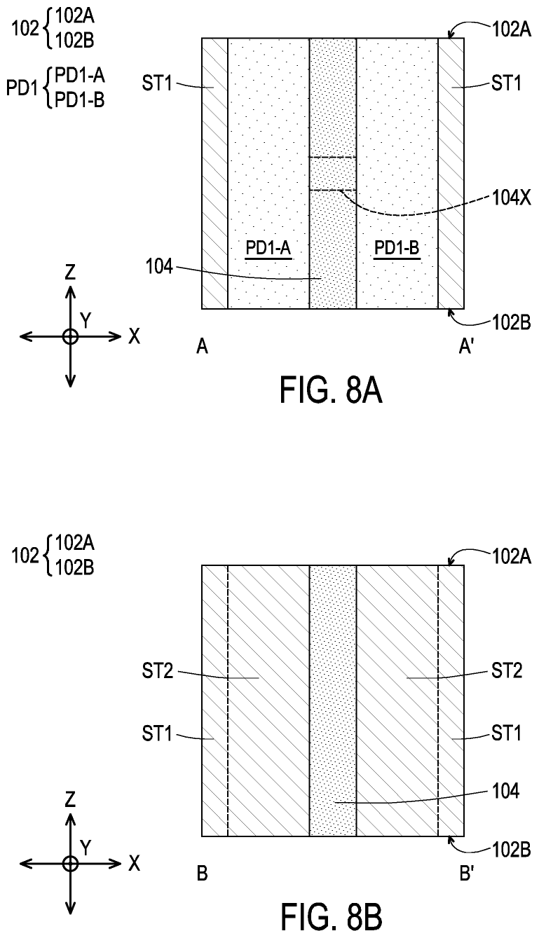

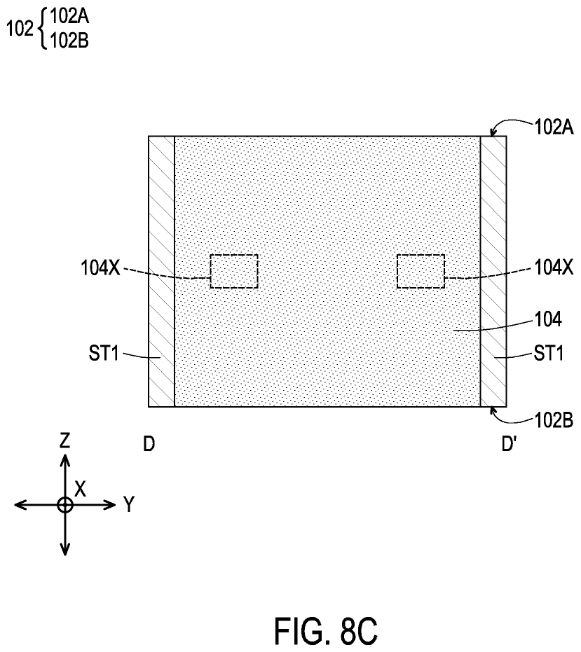

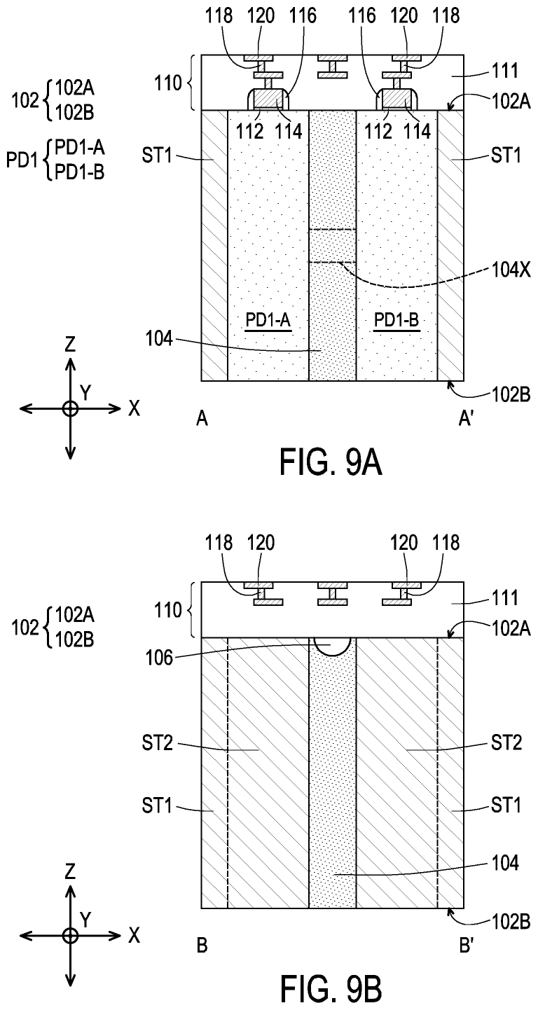

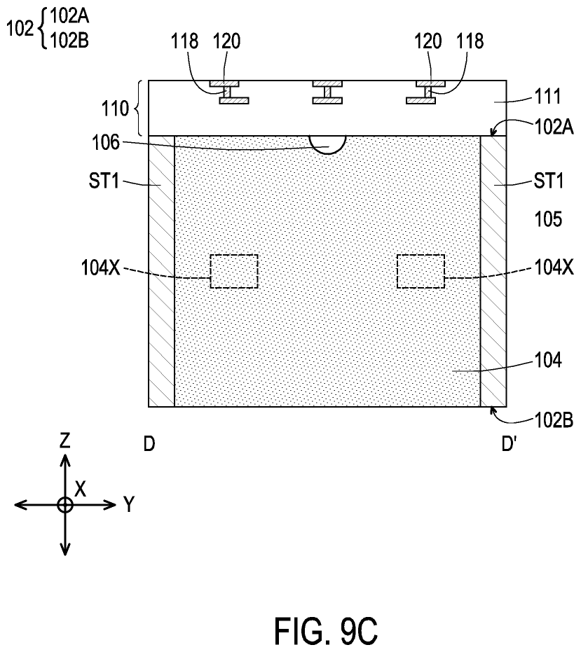

FIG. 7A to FIG. 9C are schematic sectional views of various stages in a method of fabricating the image sensor S200 according to some other exemplary embodiments of the present disclosure. FIG. 7A, FIG. 8A and FIG. 9A illustrates sectional views of various stages of fabricating the image sensor S200 corresponding to a position taken along the line A-A′ shown in FIG. 6A. Similarly, FIG. 7B, FIG. 8B and FIG. 9B illustrates sectional views of various stages of fabricating the image sensor S200 corresponding to a position taken along the line B-B′ shown in FIG. 6A. Similarly, FIG. 7C, FIG. 8C and FIG. 9C illustrates sectional views of various stages of fabricating the image sensor S200 corresponding to a position taken along the line D-D′ shown in FIG. 6A. The reference numerals used in FIG. 7A to FIG. 9C are the same as those used in FIG. 6A to FIG. 6E, thus the details are the same as that described in FIG. 6A to FIG. 6E, and some description will be omitted herein.

Referring to FIG. 7A to FIG. 7C, a substrate 102 is first provided. As shown in FIG. 7A to FIG. 7C, the substrate 102 is partially removed or patterned to form a plurality of trench openings, whereby an isolation material and a liner layer are formed in the trench openings to form the first isolation structure ST1 and the second isolation structure ST2. For example, the trench openings are formed by etching (e.g., by a dry etch process and/or a wet etch process) designated regions of the substrate 102 using a masking layer. After forming the trench openings, the isolation material and the liner layer of the isolation structures (ST1, ST2) may be respectively deposited in the trench openings by a CVD process, a PVD process, an ALD process, and/or some other suitable deposition or growth process.

Referring to FIG. 8A to FIG. 8C, in a subsequent step, the substrate 102 is doped with a first dopant having a first conductivity type (e.g. n-type) to form the first photodetector PD1 including the first sub-pixel region PD1-A and the second sub-pixel region PD1-B (the first photosensing region). The second photodetector PD2 is formed in a similar manner, thus its details will be omitted herein. In some embodiments, the substrate 102 is further doped to form the first deep well region 104 of the second conductivity type (e.g. p-type). In some embodiments, some regions in the first deep well region 104 are lightly doped, or doped with a lower concentration to form electron interflow regions 104X, which allows electron interflow between the sub-pixels (between PD1-A and PD1-B, or between PD2-A and PD2-B).

In the exemplary embodiment, an ion implantation process is performed on the first surface 102A of the substrate 102 to form the doped regions of the first photodetector PD1 and the second photodetector PD2, and to form the first deep well region 104. For example, the ion implantation process comprises: selectively forming a masking layer (not shown) over the first surface 102A of the substrate 102; performing a selective ion implantation process according to the masking layer, thereby implanting one or more dopants within the substrate 102; and performing a removal process to remove the masking layer (not shown).

Referring to FIG. 9A to 9C, after forming the doped regions of the first photodetector PD1 and the second photodetector PD2, the transistor devices (112, 114) and the interconnect structure 110 are formed over the first surface 102A of the substrate 102. In the exemplary embodiment, the gate dielectric layer 112 and the gate electrode 114 are formed on the substrate 102 by deposition processes such as, atomic layer deposition (ALD), chemical vapor deposition (CVD), physical vapor deposition (PVD), or the like. In yet another embodiment, the transistor devices (112, 114) may be formed by one or more deposition processes, one or more patterning processes, one or more planarization processes, one or more ion implantation processes, and/or some other suitable processes.

In some embodiments, forming the interconnect structure 110 includes forming conductive vias 118 and conductive wires 120, and forming interconnect dielectric structure 111 surrounding the transistor devices (112, 114) and surrounding the conductive vias 118 and conductive wires 120. In some embodiments, the interconnect dielectric structure 111 formed by one or more deposition process(es) such as a physical vapor deposition (PVD) process, a chemical vapor deposition (CVD) process, an atomic layer deposition (ALD) process, another suitable growth or deposition process, or any combination of the foregoing. Furthermore, the conductive vias 118 and conductive wires 120 may be formed by one or more deposition processes, one or more patterning processes, one or more planarization processes, or some other suitable processes.

After forming the interconnect structure 110 on the first surface 102A of the substrate 102, the structure illustrated in FIG. 9A to FIG. 9C is flipped around to reveal the second surface 102B of the substrate 102. Thereafter, a dielectric layer 125, a grid structure 130, the color filters (CL1, CL2) and the micro-lens (ML1, ML2) may be respectively formed/disposed over the second surface 102B of the substrate 102 to accomplish the image sensor S200 illustrated in FIG. 6A to FIG. 6E.

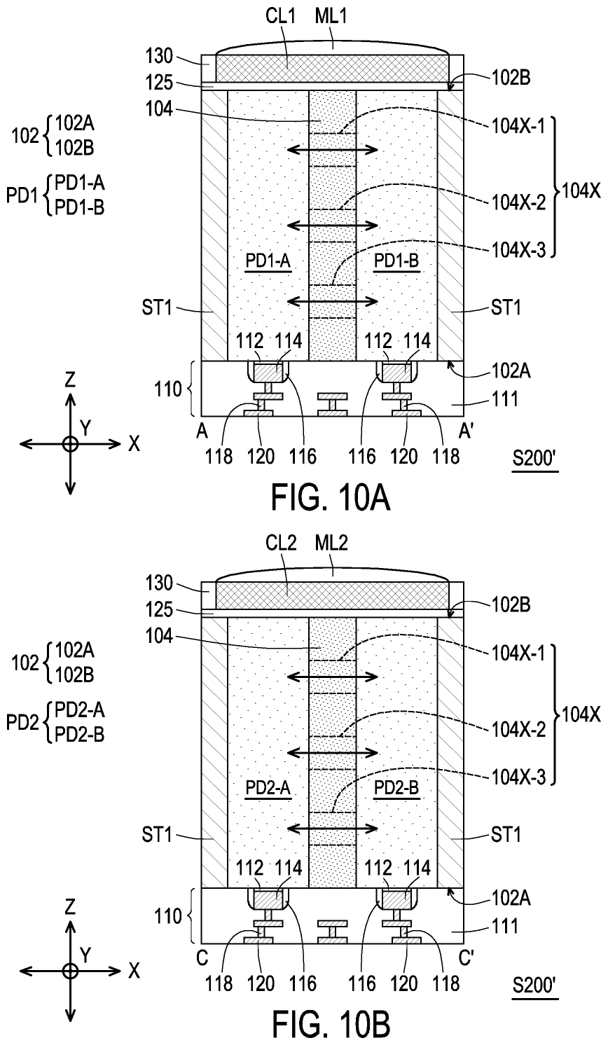

FIG. 10A and FIG. 10B are schematic sectional views of an image sensor in accordance with some other embodiments of the present disclosure. The image sensor S200′ illustrated in FIG. 10A and FIG. 10B is similar to the image sensor S200 illustrated in FIG. 6A to FIG. 6E. Therefore, the same reference numerals are used to refer to the same or like parts, and its detailed description will be omitted herein. The difference between the embodiments is in the design of the electron interflow region 104X.

In the embodiment illustrated in FIG. 6A to FIG. 6E, the first deep well region 104 includes a single electron interflow region 104X (first electron interflow region) in the first photodetector PD1 allowing electrons to pass from the first sub-pixel region PD1-A to the second sub-pixel region PD1-B, and a single electron interflow region 104X (second electron interflow region) in the second photodetector allowing electrons to pass from the third sub-pixel region PD2-A to the fourth sub-pixel region PD2-B. However, the disclosure is not limited thereto, and there may be multiple electron interflow regions 104X (or sub-regions) in the first photodetector PD1 and the second photodetector PD2. For example, referring to FIG. 10A, in the first photodetector PD1, the electron interflow region 104X (first electron interflow region) includes a plurality of electron interflow sub-regions 104X-1, 104X-2, 104X-3 allowing electrons to pass from the first sub-pixel region PD1-A to the second sub-pixel region PD1-B. Furthermore, referring to FIG. 10B, in the second photodetector PD2, the electron interflow region 104X (second electron interflow region includes a plurality of electron interflow sub-regions 104X-1, 104X-2, 104X-3 allowing electrons to pass from the third sub-pixel region PD2-A to the fourth sub-pixel region PD2-B. For example, the number of electron interflow region 104X (or sub-regions) in the first photodetector PD1 and the second photodetector PD2 may be the same.

In the image sensor S200′ of FIG. 10A and FIG. 10B, the image sensor S200′ has a further simplified DTI architecture including the first isolation structure ST1 and the second isolation structures ST2. As such, the DTI structure in the image sensor S200′ can be formed with lower etching bias (lower damage), and a white pixel (WP) performance can be improved. In addition, by removing the DTI structure in between sub-pixels (between PD1-A and PD1-B, or between PD2-A and PD2-B), an electron interflow region between the sub-pixels is no longer restricted by the DTI design, and can be arranged at any depth along the substrate 102. As such, a more flexible design of the image sensor S200′ can be achieved.

In the above embodiments, the image sensor includes first photosensing regions and second photosensing regions disposed within a substrate, whereby a first deep well region is physically separating the first photosensing regions from one another, and physically separating the second photosensing regions from one another. Furthermore, the image sensor is designed with a simplified DTI architecture including the first isolation structure and the second isolation structures. As such, the DTI structure in the image sensor can be formed with lower etching bias (lower damage), and a white pixel (WP) performance can be improved. Furthermore, the DTI structure in between sub-pixels are removed. As such, an electron interflow region between the sub-pixels is no longer restricted by the DTI design, and can be arranged at any depth along the substrate.

In accordance with some embodiments of the present disclosure, an image sensor includes a plurality of first photosensing regions, a plurality of second photosensing regions, a first deep well region, a first isolation structure and second isolation structures. The first photosensing regions and the second photosensing regions are disposed within a substrate, and have a first conductivity type. The substrate includes a first surface and a second surface opposite to the first surface. The first deep well region has a second conductivity type, and is extending from the first surface to the second surface and physically separating the plurality of first photosensing regions from one another, and physically separating the plurality of second photosensing regions from one another, wherein the second conductivity type is opposite to the first conductivity type. The first isolation structure is extending from the first surface to the second surface and laterally surrounding the plurality of first photosensing regions and the plurality of second photosensing regions. The second isolation structures are extending from the first surface to the second surface, and disposed in between the plurality of first photosensing regions and the plurality of second photosensing regions.

In accordance with some other embodiments of the present disclosure, an image sensor includes a substrate, a first photodetector, a second photodetector, a first deep well region, a first isolation structure, a first micro-lens and a second micro-lens. The first photodetector is disposed within the substrate and includes a first sub-pixel region and a second sub-pixel region. The second photodetector is disposed within the substrate and includes a third sub-pixel region and a fourth sub-pixel region, wherein the second photodetector is physically separated from the first photodetector. The first deep well region is disposed in between the first sub-pixel region and the second sub-pixel region, and disposed in between the third sub-pixel region and the fourth sub-pixel region, wherein the first deep well region includes a first electron interflow region allowing electrons to pass from the first sub-pixel region to the second sub-pixel region and a second electron interflow region allowing electrons to pass from the third sub-pixel region to the fourth sub-pixel region. The first isolation structure is laterally surrounding the first photodetector and the second photodetector. The first micro-lens is disposed on and overlapped with the first sub-pixel region, the second sub-pixel region, and the first deep well region. The second micro-lens is disposed on and overlapped with the third sub-pixel region, the fourth sub-pixel region, and the first deep well region.

In yet another embodiment of the present disclosure, a method of fabricating an image sensor is described. The method includes the following steps. A substrate is doped to form a plurality of first photosensing regions and a plurality of second photosensing regions in the substrate, wherein the first photosensing regions and the second photosensing regions have a first conductivity type, and the substrate includes a first surface and a second surface opposite to the first surface. The substrate is doped to form a first deep well region of a second conductivity type extending from the first surface to the second surface, wherein the first deep well region is physically separating the first photosensing regions from one another, and physically separating the second photosensing regions from one another, and wherein the second conductivity type is opposite to the first conductivity type. The substrate is patterned to form a first isolation structure extending from the first surface to the second surface, wherein the first isolation structure is laterally surrounding the first photosensing regions and the second photosensing regions. The substrate is patterned to form second isolation structures extending from the first surface to the second surface, wherein the second isolation structures are disposed in between the first photosensing regions and the second photosensing regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a plurality of first photosensing regions and a plurality of second photosensing regions disposed within a substrate, wherein the plurality of first photosensing regions and the plurality of second photosensing regions have a first conductivity type, and the substrate comprises a first surface and a second surface opposite to the first surface;
a first deep well region of a second conductivity type extending from the first surface to the second surface and physically separating the plurality of first photosensing regions from one another, and physically separating the plurality of second photosensing regions from one another, wherein the second conductivity type is opposite to the first conductivity type;
a first isolation structure extending from the first surface to the second surface and laterally surrounding the plurality of first photosensing regions and the plurality of second photosensing regions; and
second isolation structures extending from the first surface to the second surface, and disposed in between the plurality of first photosensing regions and the plurality of second photosensing regions.

2. The image sensor according to claim 1, wherein the second isolation structures are physically joined with the first isolation structure.

3. The image sensor according to claim 2, wherein the second isolation structures are contacting sidewalls of the first deep well region.

4. The image sensor according to claim 1, further comprising a second deep well region of the second conductive type extending from the first surface of the substrate to a first depth into the substrate, and physically separating the plurality of first photosensing regions from the plurality of second photosensing regions, and wherein the second deep well region has a higher doping concentration than the first deep well region.

5. The image sensor according to claim 4, further comprising a third isolation structure extending from the second surface of the substrate towards a position into the second deep well region.

6. The image sensor according to claim 5, wherein the second isolation structures are contacting sidewalls of the third isolation structure and contacting sidewalls of the second deep well region.

7. The image sensor according to claim 1, further comprising a floating diffusion node disposed in the substrate and located in between the second isolation structures.

8. The image sensor according to claim 1, further comprising a first micro-lens disposed on the second surface of the substrate and overlapped with the plurality of first photosensing regions and the first deep well region.

9. An image sensor, comprising:
a substrate;
a first photodetector disposed within the substrate and comprising a first sub-pixel region and a second sub-pixel region;
a second photodetector disposed within the substrate and comprising a third sub-pixel region and a fourth sub-pixel region, wherein the second photodetector is physically separated from the first photodetector;
a first deep well region disposed in between the first sub-pixel region and the second sub-pixel region, and disposed in between the third sub-pixel region and the fourth sub-pixel region, wherein the first deep well region comprises a first electron interflow region allowing electrons to pass from the first sub-pixel region to the second sub-pixel region and a second electron interflow region allowing electrons to pass from the third sub-pixel region to the fourth sub-pixel region;
a first isolation structure laterally surrounding the first photodetector and the second photodetector;
a first micro-lens disposed on and overlapped with the first sub-pixel region, the second sub-pixel region, and the first deep well region; and
a second micro-lens disposed on and overlapped with the third sub-pixel region, the fourth sub-pixel region, and the first deep well region.

10. The image sensor according to claim 9, wherein the first electron interflow region comprises a plurality of electron interflow sub-regions allowing electrons to pass from the first sub-pixel region to the second sub-pixel region, wherein the plurality of electron interflow sub-regions are regions having a lowest doping concentration in the first deep well region.

11. The image sensor according to claim 9, further comprising a second deep well region physically separating the first sub-pixel region and the second sub-pixel region from the third sub-pixel region and the fourth sub-pixel region, wherein the second deep well region has a higher doping concentration than the first deep well region.

12. The image sensor according to claim 11, further comprising an auxiliary isolation structure physically separating the first sub-pixel region and the second sub-pixel region from the third sub-pixel region and the fourth sub-pixel region, wherein the auxiliary isolation structure is joined to the second deep well region, and a height of the auxiliary isolation structure is smaller than a height of the first isolation structure.

13. The image sensor according to claim 12, further comprising a second isolation structure physically joined with the first isolation structure, and contacting sidewalls of the auxiliary isolation structure, and contacting sidewalls of the second deep well region, wherein a height of the second isolation structure is equal to the height of the first isolation structure.

14. The image sensor according to claim 12, further comprising a floating diffusion node embedded in the second deep well region and overlapped with the auxiliary isolation structure.

15. The image sensor according to claim 9, wherein the first sub-pixel region, the second sub-pixel region, the third sub-pixel region and the fourth sub-pixel region are n-type doped regions, and the first deep well region is a p-type doped region.

16. A method of fabricating an image sensor, comprising:
doping a substrate to form a plurality of first photosensing regions and a plurality of second photosensing regions in the substrate, wherein the plurality of first photosensing regions and the plurality of second photosensing regions have a first conductivity type, and the substrate comprises a first surface and a second surface opposite to the first surface;
doping the substrate to form a first deep well region of a second conductivity type extending from the first surface to the second surface, wherein the first deep well region is physically separating the plurality of first photosensing regions from one another, and physically separating the plurality of second photosensing regions from one another, and wherein the second conductivity type is opposite to the first conductivity type;
patterning the substrate to form a first isolation structure extending from the first surface to the second surface, wherein the first isolation structure is laterally surrounding the plurality of first photosensing regions and the plurality of second photosensing regions; and
patterning the substrate to form second isolation structures extending from the first surface to the second surface, wherein the second isolation structures are disposed in between the plurality of first photosensing regions and the plurality of second photosensing regions.

17. The method according to claim 16, wherein the second isolation structures are formed to be physically joined with the first isolation structure.

18. The method according to claim 16, further comprising doping the substrate to form a second deep well region of the second conductive type extending from the first surface of the substrate to a first depth into the substrate, wherein the second deep well region is physically separating the plurality of first photosensing regions from the plurality of second photosensing regions, and wherein the second deep well region has a higher doping concentration than the first deep well region.

19. The method according to claim 18, further comprising patterning the substrate to form a third isolation structure extending from the second surface of the substrate towards a position into the second deep well region.

20. The method according to claim 16, further comprising forming a floating diffusion node in the substrate, wherein the floating diffusion node is located in between the second isolation structures.
